(19) United States
(12) Patent Application Publication
(10) Pub. No.: US 2011/0206841 A1
(43) Pub. Date: Aug. 25, 2011

(54) METHOD AND DEVICE FOR CONDITIONING PAPER

(76) Inventor: Jordi Sabater Vilella, Sant Cugat Del Valles (Barcelona) (ES)

(21) Appl. No.: 12/301,808

(22) PCT Filed: May 22, 2007
(86) PCT No.: PCT/ES07/00295

§ 371 Date: Dec. 16, 2008

(30) Foreign Application Priority Data
May 22, 2006 (ES) P 2006 01318

(51) Int. Cl. B05D 3/00; B05D 1/00; B05D 7/00; B05C 11/00; B05C 9/10; C23C 16/02; C23C 16/44; B05D 1/38

(52) U.S. Cl. 427/248.1; 427/326; 427/398.1; 118/69; 118/715; 118/712; 118/726

(57) ABSTRACT

Method for conditioning paper, which comprises a first step of cooling and one of applying a liquid to the paper. In the cooling step, the temperature of the paper is reduced, e.g. below ambient temperature or below the dew point of a liquid-saturated gas mass applied in the liquid-application step. The gas may be ambient air and the liquid water. Control means monitor the amount of liquid applied to the paper by means of measuring the relative humidity of the air, the absolute humidity of the paper, the temperature of the device where the liquid is applied and the temperature of the paper. The invention also comprises a device for applying the method and it may be applied to paper emerging from a printer, e.g. a digital printer.

This invention relates to a process and device for conditioning paper.

In particular this invention relates to a process and device for conditioning paper in printing systems, and more particularly in digital printing systems, although the invention should not necessarily be restricted to that application.

High volume printing systems based on electronics (“digital printing”) arose from companies' needs to be able to print flows of personalised documentation in a short space of time. By generating digital files converted into individual printed documents using continuous paper printers these systems have grown in capacity and print quality to extend into graphic art products, allowing these new printing systems to penetrate new markets with a high growth potential, such as the Graphic Arts market. This technology makes it possible to print small runs of products which would be impossible to produce using conventional Offset printing methods.

The special features of these digital printing technologies which do away with plates in order to transfer images onto the substrate, through the combined use of electrostatic and electromagnetic charges, of electronic origin, based charges, etc., make it necessary to act on the substrate or paper in order to permanently fix the emulsion used to print the text thereon. For this purpose known techniques make use of a number of processes which act on the substrate, once the dry ink or toner has been deposited upon it, by means of which said emulsion can be permanently fixed. Conversely, offset technology uses inks based on water or other liquids which are fixed on a substrate by absorption. In digital systems these fixing processes produce changes in the substrate in the form of electrostatic charges, the loss of moisture, or physical distortion of the substrate through contraction or expansion which severely affect subsequent handling processes, finish and the final product. These changes also result in making the processes more expensive as they limit possible applications for digital printing technology, a problem which has not been suitably solved. As a consequence, existing techniques give rise to problems when digital printing is applied as a replacement for other printing techniques such as offset for the production of large runs of printed matter, books, etc.

A device for rehumidifying printed paper in digital printing systems based on moistening the paper by spraying a jet of water onto the strip is known. However, this device does not resolve the problem mentioned above, for the following reasons: electronic or digital printers subject the printed paper strip to toner fixing or drying processes which give rise to sudden loss of moisture from the paper (+/−50%) down to levels of 3%. This produces the effects of distortion of the paper and static electricity charges which make the costs of printing and post-treatment more expensive, as explained above. The process carried out by this device of a known type is based on attacking a consequence of the problem, that is to say adding water to compensate for the dryness of the paper as it leaves the printing process. The problem is that this must be done using paper which has just emerged from the harsh working conditions of printers at temperatures above 45° C. going up to 90° C. Because of the hygroscopic nature of paper, the size of the microdroplets produced by spraying the water and the temperature of the paper, the jet evaporates as a result of the radiation emitted by the paper in a zone some 10 mm on each side of the paper strip. This rejection effect causes the drops of water to join together through the effect of surface tension, increasing in size beyond undesirable levels to the point that they fall onto the moving surface. As a consequence the desired humidity is never recovered, the paper evaporates most of it and the interior (core) remains dry, retaining its sensitivity to static charges without eliminating these during handling processes. According to tests carried out by the inventor, another consequence of this effect is that it is difficult to control the quantity of liquid which is effectively applied to the paper, because of the evaporation caused by the temperature. It must be added that other important consequences of this process used by this machine are curling of the paper once it is cut and a rough surface finish which is prejudicial to its quality, produced by the drops which fall randomly on the paper through the effect of surface tension and the heat radiated by the paper.

The consequent effects of the mentioned physical effects on the paper can be evaluated in operating terms affecting production, labour, costs of raw materials and financial costs.

In market terms we can put the number of facilities currently in operation at 20,000 continuous paper digital printing systems throughout the world. The future and potential market includes the entire graphics industry throughout the world, and therefore it is very difficult to establish an approximate figure, although it is estimated that the number of companies included in this production group is some five million throughout the world. Specifically it is clear that there is an unsatisfied technical need to provide effective paper conditioning systems which do not present the problems of currently known devices, especially with reference to digital printing systems.

In order to provide a solution for the problems mentioned above this invention comprises a process for the conditioning of paper, preferably the conditioning of printed paper, more preferably paper printed by means of digital printing, characterised in that it comprises a stage of cooling the paper and a subsequent stage of applying liquid (rehumidifying water and/or other surface treatment liquids) onto the cooled paper, preferably by exposing the paper to a mass of gas containing vapour of the liquid being applied, the temperature of the paper being lower than the dew point of the mass of gas. Preferably the mass of gas will be a saturated mass of gas and the paper will be cooled below its dew point, so that there will be a transfer of liquid from the gas to the paper immediately upon contact between the paper and the gas. One aim is that the quantity of liquid (for example water) necessary to restore its moisture level to the values required for subsequent use or handling will be provided to the paper. Advantageously the moist gas used may be ambient air.

This invention is based on a combination of two effects, cooling and the application of liquid or humidifying, to condition the physical state of the paper and achieve hygroscopic stability, bringing about treatment of the core of the paper in preferred applications, which has not been achieved hitherto. There is no similar process for this purpose in the industry, for the technical conditions for which it applies.

In this invention the term paper must not be understood as being limited to exclusively cellulose printing substrates, but must be regarded as including any printing substrate with or without a cellulose component which has a structure similar to that of cellulose paper.

The solution provided by this invention applied to the conditioning of printed paper in digital printing systems is based on addressing the problem at its source and not with its consequences, eliminating the heat carried by the paper through a system of cooling which preferably brings the temperature of the paper as close as possible to a dew point which will depend on the temperature of the room and the relatively humidity level of the environment interacting with the temperature and relatively humidity of the environment in which the printers are located, down to the dew point, to take advantage in this way of the hygroscopic nature of the paper which picks up moisture from the environment in a natural way. However, in many cases the premises in which the activity of printing and/or finishing is carried out have no control over environmental humidity although they may have temperature control. Because the activity of these systems generates heat, part of this dissipates into the room, which means that it must be cooled by air conditioning, which dries the environment. In such a dry environment, with standard environmental relative humidity values of 25/30%, it is necessary to add moisture to the paper while maintaining the dew point, through the effect of the cooling system, just before the paper comes into equilibrium with the conditions in the room, producing the said effect quickly. Thus humidification must be applied preferably just at the moment of cooling or immediately afterwards. The process can be carried out using any cooling system which permits control of the temperature resulting from combination of the ambient relative humidity and the room temperature. Thus humidification of the paper is a process which can for example be carried out through the use of sprays or by generating cold or hot vapour, or by means of a jet of moisture-saturated air, a system with the ability to instantly vary the volume of water transferred to the paper by the said system, and to provide just the amount required at every moment, independently of the environmental conditions in the room, making use of the advantages obtained by prior cooling of the paper.

The spray technique may also be used to apply a liquid for treating the paper onto the paper, for example in order to generate a layer protecting the printed image.

Among other advantages this invention makes it possible to use papers for offset printing in digital printing systems which are cheaper than the “laser” papers which are treated to resist the adverse effects deriving from the processes of fixing toner, which brings about a cost saving of some 20% in raw materials. Another advantageous aspect of this invention is that it permits increases in output of 50 to 100% as a result of the increased speed in handling and finishing processes deriving from the absence of electrostatic charges, which means that the operating cycles indicated for the machines by their manufacturers can be achieved, as at the present time these cycles hardly ever exceed 50% of the stated printing speed.

The elimination of deformations caused to the substrate during the printing process which can be achieved through this invention reduces jams and stoppages, and minimises rejects of printed documents. Thermal stability improves the performance and precision of post-processing equipment and reduces wear and maintenance, resulting in a clear benefit for the manufacturers of such equipment. The increased output from the machines reduces production times releasing more workload and therefore offering greater production capacity at lower cost and without additional investment, opening up a greater capacity for personalisation which will benefit printer manufacturers through increases in the direct receipt of “clicks” and generating growth expectations for the sale of new hardware and software equipment.

The combination or consecutive action of cooling and applying liquid, with control of temperature and the quantity of liquid applied at any time by means of automatic or manual adjustment with regulators which respond to the data provided by individual sensors of the environmental relative humidity, the absolute humidity of the paper during the said production and post-production processes, ambient temperature, the internal temperature within the system, the temperature of the paper during transfer, etc., makes it possible to achieve maximum levels of equilibrium for the paper with absolute control over the result, making it possible to act dynamically with a precision which has never previously been achieved.

According to tests carried out by the inventor, as a consequence of using this process the paper absorbs the necessary moisture uniformly over its entire surface with a balanced distribution which immediately penetrates the “core” of the paper, permitting natural expansion of the fibres making up its mass and restoring its natural hygroscopic properties and the insulating capacity of the plant fibre of which it is made up. Through this effect, which can be achieved through prior cooling and subsequent humidifying of the previously cooled paper, it is possible to act with total control over the paper/substrate, making it possible to alter process parameters during production cycles in order to produce the desired effect when the paper/substrate is fully in movement.

The invention also makes it possible to use paper handling devices in digital printing systems whose use is problematical in present techniques, such as for example:

Coil to coil: in subsequent handling processes the paper is wholly free from charges and flat without physical distortions, so the machines can be accelerated to twice the speed previously reached.

Coil, cutter/stacker: the paper runs smoothly and stably along the whole production line, remaining cold until it reaches room temperature. There is a total absence of static charges even when the paper/substrate is placed in the stacker/accumulator after being cut and the resulting packets are deposited on the belts, from which they are withdrawn by the operator; these belts are generally of rubber and do not have discharging components connected to the system for discharging the mass of the machine. They likewise remain flat and without distortion. This physical behaviour reduces jams, assists problem-free printer stopping and starting and makes it possible to accelerate the machines up to more than 100% than previously.

According to this invention the liquid applied may be water, in order to humidify the paper, or water with additives to reduce surface tension and to help electrostatic discharging by contact with the surfaces connected to the equipment's earth, or a surface varnish to treat the paper of the digitally printed surface, for example, may also be applied. In the preferred embodiment a first stage of applying water to rehumidify the paper and a second stage of applying another liquid to treat the surface of the paper may be combined with advantageous synergistic results.

This invention also comprises a device for conditioning paper comprising a device for cooling the paper, preferably for cooling below ambient temperature, and more preferably below the dew point, and a humidifier located as a continuation of the cooling device. Preferred embodiments of the device will correspond to adaptations of the device to carry out the preferred forms of the procedure to which this invention relates.

Drawings of embodiments of this invention are attached by way of an explanatory but not limiting example for a better understanding of the invention.

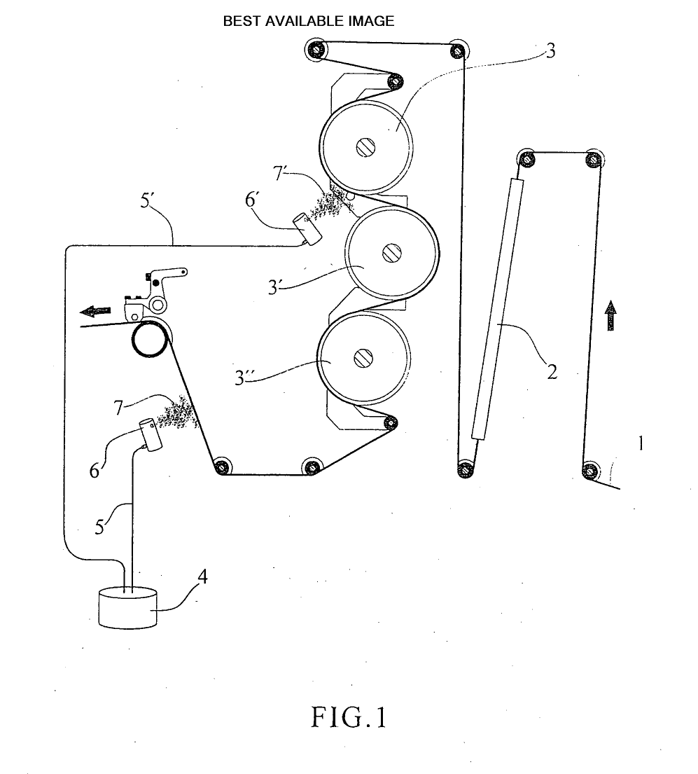

FIG. 1 is an elevation view which shows an embodiment of the device according to this invention in diagrammatical form.

FIG. 1 shows a diagram of a possible embodiment of this invention which can be positioned for example as a continuation of a digital printing device. It would also be possible to integrate the device shown as an appendage to a digital printing machine or device. In the device shown a printing substrate or paper -1- enters a first cooling zone -2- after passing through an entry zone into the device. This cooling zone may comprise cooled plates close to paper -1- in a flow of cold dry gas, or any other known system. After this first zone, in the embodiment illustrated there is a second zone providing cooling through three rollers -3-, -3′-, -3″-, the central roller of which has the ability to move in order to vary the angle of contact between cooling rollers -3-, -3′-, -3″- and paper -1-. The function of these rollers may be similar to that disclosed in documents ES2222089 and ES2222110, both corresponding to inventions by the inventor of this patent.

The device shown also comprises a storage zone -4-, which through corresponding feeds -5-, -5′- feeds dispensers -6-, -6′- for humidifying the paper. The fluid dispensed -7-, -7′- may be air having a specific moisture content and/or agents for treating paper -1-, or may be a sprayed liquid, such as water or an emulsion for treating paper and/or the printing provided on the paper itself. In this case dispenser or dispensers -6-, -6′- will preferably comprise sprays. In the example illustrated two humidifying zones represented by dispensers -6- and -6′- respectively are provided. Dispenser -6′- may for example apply water in order to rehumidify the paper, while for example second dispenser -6- may apply a protective varnish to the printing on the paper. The number of zones for humidifying or applying liquid may vary according to the needs of the process, humidification always taking place through a process of cooling the paper being treated, and preferably immediately after cooling, as in the example shown. In particular, any known method of applying liquid to a paper may be used.

In the case where treatment fluid -7-, -7′- is a gas having a particular moisture content, the paper will be cooled below its dew point. In this way the moisture present in the treatment gas will condense and humidify the paper when it comes into contact with paper at a temperature below the dew point.

The gas containing moisture may for example be air taken from the environment, of course moved by means to draw in a flow of air from the environment and place it in contact with the paper, which will ensure renewal of the same. Nevertheless, given that on occasions the room air may be treated (cooled), its moisture content may be low and it may be preferable to provide means to generate vapour and deliver this to the air or treatment gas, for example up to saturation, in order to obtain an economically more advantageous process. The vapour generated may also be used directly on the paper in a “cold” or “hot” state to humidify it through corresponding means, for example of a known type which is commercially available.

Although not shown on the appended diagram, the device will preferably have a controller for the moisture delivered to the paper. If humidification using moist air is used, this controller will preferably comprise devices for measuring the relative humidity of the air mass, the absolute humidity of the paper, the internal temperature of the device and the temperature of the paper.

Likewise the combination of both processes (cooling and application of liquid) will stabilise the substrate and make it possible to act on it in order to provide a final seal through the application of emulsions (varnish, silicone, etc.) which will help to optimise the final result comprising isolating the substrate from the environmental conditions of the rooms in which it is stored and/or sealed, avoiding loss of time produced by, as applicable, insufficient fusion in the fusion devices, a circumstance which gives rise to the wastage of toner used for printing the text or the printed image.

In fact one novel feature comprises the stability point necessary for application of the emulsion film (varnish, silicone, etc.) which serves the substrate. In this case, prior cooling of the substrate is essential, as in most cases the chemical composition of the substances, which is mainly based on polymer compounds, is only stable at low temperatures (between 30° C. and 5° C.), the viability of their application being necessarily determined by the temperature of the substrate, given that outside the temperatures mentioned these emulsions degrade or change, making their application non-viable. A system of application based on rollers or sprays is for example advantageous for the purpose.

1. A process for conditioning paper comprising:
a first stage of cooling the paper to a temperature below ambient temperature; and
a second subsequent stage of applying a liquid to the cooled paper.

2. (canceled)

3. The process according to claim 1, wherein the second subsequent stage of applying a liquid to the cooled paper comprises exposing the paper to a mass of gas containing vapour of the liquid to be applied, the paper having been previously cooled below the dew point of the mass of liquid in the gas.

4. The process according to claim 3, wherein the mass of gas is saturated with vapour of the liquid which is to be applied.

5. The process according to claim 3, wherein the mass of gas is in movement.

6. The process according to claim 3, wherein the mass of gas is air taken from the atmosphere.

7. The process according to claim 1, wherein the liquid is water.

8. The process according to claim 1, wherein the quantity of liquid applied to the paper is controlled.

9. The process according to claim 8, wherein said control is achieved by means of measurements of the relative humidity of a mass of air, the absolute moisture content of the paper, the internal temperature of a system carrying out the process and the temperature of the paper.

10. The process according to claim 8, wherein the control comprises altering the volume of the mass of air in contact with the paper.

11. The process according to claim 1, further comprising a stage of applying a liquid to treat the surface of the paper.

12. The process according to claim 7, wherein the application of water comprises a stage of generating water vapour.

13. The process according to claim 1, further comprising a prier stage of printing the paper.

14. The process according to claim 13, wherein the printing stage is a digital printing stage.

15. The process according to claim 13, wherein the cooling stage is carried out immediately after the printing stage.

16. The process according to claim 1, wherein water is applied immediately after the cooling stage.

17. A device for conditioning paper comprising:
a cooling component for cooling paper to below ambient temperature; and
a liquid-applying component for applying liquid to the cooled paper.

18. (canceled)

19. The device according to claim 17, wherein the liquid-applying component comprises a zone of contact between the paper and a mass of gas containing moisture.

20. The device according to claim 19, wherein the cooling component comprises means to cool the paper below the dew point of the mass of gas.

21. The device according to claim 20, wherein the liquid-applying component comprises means to draw a flow of air from the environment and place it in contact with the paper being treated.

22. The device according to claim 21, further comprising means to provide water to the air until it becomes saturated.

23. The device according to claim 17, further comprising a controller for the liquid delivered to the paper.

24. The device according to claim 23, wherein the controller comprises means for measuring at least one of the relative humidity of a mass of air, the absolute moisture content of the paper, the internal temperature of the device and the temperature of the paper.

25. The device according to claim 17, wherein the liquid-applying component comprises a spray for spraying a liquid for treating paper onto the paper.

26. The device according to claim 17, wherein the liquid-applying component comprises:
a vapour generator; and
means for placing the vapour generated in contact with the paper which is to be humidified.

27. The device according to claim 17, wherein the liquid-applying component is located at an outlet of the cooling component.

28. The device according to claim 17, further comprising a printing device whose outlet feeds the cooling component.

29. The device according to claim 28, wherein the printing device is a digital printing device.
